(19) United States
(12) Patent Application Publication
(10) Pub. No.: US 2023/0402342 A1
(43) Pub. Date: Dec. 14, 2023

(54) DUAL-SIDE COOLED EMBEDDED DIE PACKAGING FOR POWER SEMICONDUCTOR DEVICES

(71) Applicant: GaN Systems Inc., Kanata (CA)

(72) Inventors: Di CHEN, Kanata (CA); Juncheng LU, Kanata (CA); Ahmad MIZAN, Kanata (CA); Ruoyu HOU, Kanata (CA); Abhinandan DIXIT, Kanata (CA)

(21) Appl. No.: 18/094,477

(22) Filed: Jan. 9, 2023

Related U.S. Application Data
(60) Provisional application No. 63/350,562, filed on Jun. 9, 2022.

(51) Int. Cl. H01L 23/367; H01L 29/16; H01L 29/20; H01L 29/66

(52) U.S. Cl. CPC H01L 23/3672; H01L 29/1608; H01L 29/2003; H01L 29/66462

(57) ABSTRACT

Embedded die packaging for high voltage, high temperature operation of power semiconductor switching devices is disclosed, wherein a power semiconductor die is embedded in laminated body comprising a layer stack of a plurality of dielectric layers and electrically conductive layers, and wherein a first thermal pad on one side of the package and a second thermal pad on an opposite side of the package provides for dual-side cooling. Example embodiments of the dual-side cooled package may be based on a bottom-side cooled layup with a primary bottom-side thermal pad and a secondary top-side thermal pad, or a top-side cooled layup with primary top-side thermal pad and a secondary bottom side thermal pad, using layups with or without a leadframe. For example, the power semiconductor switching device comprises a GaN power transistor, such as a GaN HEMT rated for operation at ≥100V or ≥600V, for switching tens or hundreds of Amps.

### CROSS-REFERENCE TO RELATED APPLICATION(S)

This application claims priority from U.S. provisional patent application No. 63/350,562, filed Jun. 9, 2022, entitled “Dual Side-Cooled Embedded Die Packaging for Power Semiconductor Devices”, which is incorporated herein by reference in its entirety.

This application is related to U.S. patent application Ser. No. 17/728,220 filed Apr. 25, 2022, entitled “Embedded Die Packaging for Power Semiconductor Devices” which is a continuation of U.S. patent application Ser. No. 16/298,305, filed Jul. 14, 2020, of the same title; both applications are incorporated herein by reference in their entirety.

### TECHNICAL FIELD

This invention relates to embedded die packaging for power semiconductor devices, such as Gallium Nitride (GaN) High Electron Mobility Transistors (HEMTs) for high voltage and high current operation.

### BACKGROUND

GaN power transistors, such as GaN HEMTs, provide for high current, high voltage operation combined with high switching frequency. For some power applications, GaN power devices and systems offers advantages over silicon technology using Si IGBTs and diodes and SiC power transistors and diodes. For example, power switching systems comprising lateral GaN transistors provide higher efficiency switching, with lower losses, and smaller form factor than comparable systems based on silicon or SiC technology. To benefit from the inherent performance characteristics of lateral GaN transistors, important design considerations include, e.g.: device layout (topology), low inductance interconnect and packaging, and effective thermal management. Lateral GaN power transistors for high current operation at 100V and 650V operation are currently available from GaN Systems Inc. based on Island Technology® that provides a large gate width W_{g}, low on-resistance, Rₒₙ, and high current capability per unit active area of the device.

Embedded die packaging solutions that offer low inductance interconnections, and low thermal impedance, are disclosed, for example, in U.S. patent application Ser. No. 16/298,305, filed Jul. 14, 2020, entitled “Embedded Die Packaging for Power Semiconductor Devices”, references cited therein, and non-patent publications relating to GaNPx® embedded die packaging. U.S. Ser. No. 16/298,305 discloses embedded die packaging for power semiconductor devices which comprises a laminated structure built up from layers of dielectric materials and conductive metal layers. This type of laminated embedded die packaging provides low parasitic inductance in a compact (i.e. small form factor) package for high voltage, high current GaN e-HEMTs. For example, a 100V, 90 A GaN e-HEMT (GS61008T) may be provided in a top-side cooled laminated package which is about 7 mm×4 mm, and 0.54 mm thick; a 650V, 60 A GaN e-HEMT (GS66516T) may be provided in a laminated package which is 9 mm×7.6 mm and 0.54 mm thick.

GaN power switching devices, such as those mentioned above offered by GaN Systems Inc., which are embedded in a GaNPX type laminated package of small size, e.g. 7 mm×5 mm and 0.5 mm thick, are capable of operation at voltages in a range from 100V to 650V, for switching currents of tens or hundreds of Amps. Operating temperatures may reach or exceed 100 C. For small size dies having a high current capability per unit active area, and smaller package sizes, e.g. chip-scale packaging, package components are therefore subjected to higher electric fields and higher operating temperatures than for low voltage, lower power switching devices.

For example, high current GaN HEMTs having a smaller die size, and smaller embedded die package size, which provides higher power density, and a small area thermal pad, present challenges for thermal management. For example, a barrier to further improve thermal performance of bottom-cooled devices is limited area of the thermal pad area/size of the device. With smaller die sizes, and smaller packages, thermal performance is limited by the area of the thermal pad. On the other hand, in larger sized package, parasitics such as interconnect inductance or resistance, may limit performance of power semiconductor devices comprising GaN HEMTs, which are capable of fast switching speeds (fast turn-on and turn-off times, and operation at higher switching frequencies).

There is a need for improved or alternative embedded die packaging, particularly for high voltage/high current power switching semiconductor devices, such as GaN HEMTs, e.g., to address issues of thermal management, and/or provide improved reliability for high voltage and high temperature operation.

### SUMMARY OF INVENTION

The present invention seeks to provides improved or alternative embedded die packaging for power semiconductor devices, and particularly for high voltage/high current wide-bandgap semiconductor power switching devices, e.g. GaN HEMTs and SiC power MOSFETS, which mitigate or circumvent at least one of the above-mentioned issues.

One aspect of the invention provides an embedded die package comprising a laminated body and a die comprising a power semiconductor device, the die being embedded within the laminated body, the laminated body comprising a stack of a plurality of dielectric build-up layers and a plurality of electrically conductive layers, wherein a primary thermal pad is provided on a first side of the package and a secondary thermal pad is provided on an opposite side of the package, the primary and secondary thermal pads providing for dual-side-cooling.

In some embodiments, the laminated body is based on a bottom-side-cooled layup that provides the primary thermal pad and electrical connections for the power semiconductor device on the first side (bottom-side) of the package and wherein the secondary thermal pad is provided on the opposite side (top-side) of the package.

In some embodiments the laminated body is based on a top-side cooled layup that provides the primary thermal pad on the first side (top-side) of the package and wherein the secondary thermal pad and electrical connections for the power semiconductor device are provided on the opposite side (bottom-side) of the package.

For example, in some embodiments the embedded die package comprises a leadframe provided by one of said plurality of electrically conductive layers, the leadframe supporting the die within the laminated body and providing said first thermal pad.

For example, an embedded die package comprises a laminated body and a die comprising a power semiconductor device, the die being embedded within the laminated body, wherein: the die comprises a patterned layer of conductive metallization on a front-side (active-side) of the die providing electrical contact areas of the semiconductor power device, and a thermal contact area on a back-side of the die; and

a layer stack of the laminated body comprises:
a core comprising at least one dielectric layer which embeds the die;
at least first, second and third conductive metal layers which are separated by intervening dielectric layers of the layer stack;
the first conductive metal layer providing a first thermal pad which is in thermal contact with the thermal contact area on the back-side of the die;
the second conductive metal layer being patterned to define internal electrical interconnect areas; the internal electrical interconnect areas of the second conductive layer being connected by electrically conductive vias to respective electrical contact areas on the front-side of the die; and
the third conductive metal layer providing a second thermal pad overlying at least part of the second conductive metal layer;
external electrical contact areas of the power semiconductor device provided on a bottom-side of the package, respective internal electrical contact areas and external electrical contact areas being interconnected; and
wherein the first and second thermal pads provide for dual-side cooling of the die.

Thermal vias may be provided for said thermal contact between the first thermal pad and the thermal contact on the back-side of the die.

In some embodiments, a fourth conductive layer is provided underlying the first conductive layer, the fourth conductive layer forming an external thermal pad which is in thermal contact with the first thermal pad of the first conductive layer, and thermally conductive vias provide thermal contact between the first thermal pad and the external thermal pad.

In some embodiments, the first conductive layer comprises a leadframe supporting the die, and wherein said first thermal pad is provided by an exposed surface of the leadframe.

For example, the power semiconductor device comprises a lateral power transistor, wherein said electrical contact areas of the semiconductor power device comprise contact areas for a source, drain and gate of the lateral power transistor, and wherein the first thermal pad and the second thermal pad are internally connected to the source. Vias comprising electrically conductive and thermally conductive material may provide electrical connection and thermal contact between the first thermal pad and the source, and between the second thermal pad and the source.

For example, another aspect provides an embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a primary thermal pad, the thermal contact area of the die being in thermal contact with the primary thermal pad of the leadframe;
a first dielectric build-up layer embedding the die and the leadframe;
a second conductive layer on the first dielectric build-up layer;
the second conductive layer being patterned to define interconnect areas;
the interconnect areas of the second conductive layer being connected by electrically conductive vias to respective electrical contact areas of the power semiconductor device and electrical contact areas of the leadframe; and
a second dielectric build-up layer on the second conductive layer;
a third conductive layer on the second dielectric build-up layer;
the third conductive layer being patterned to define a secondary thermal pad;
wherein the primary and secondary thermal pads providing for dual-side cooling

For example, another aspect provides an embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a core comprising at least one dielectric layer which embeds the die;
a first dielectric build-up layer on a first side of the core;
a first conductive layer on the first dielectric build-up layer;
the first conductive layer being patterned to define a primary thermal pad and electrical interconnect areas, the thermal contact area of the die being in thermal contact with the primary thermal pad;
a second dielectric build-up layer on a second side of the core,
a second conductive layer on the second dielectric build-up layer,
the second conductive layer being patterned to define electrical contact areas, the interconnect areas of the first conductive layer being connected by electrically conductive vias to respective electrical contact areas of the power semiconductor device and respective electrical contact areas of the first conductive layer;
a third dielectric build-up layer on the first conductive layer;
a third conductive layer on the third dielectric build up layer;
the third conductive layer being patterned to define a secondary thermal pad;
wherein the primary and secondary thermal pads providing for dual-side cooling.

Thus, embedded die packages of example embodiments provide for improvements in embedded die packaging for power semiconductor switching devices which provide for dual-side-cooling. Example embedded die packages provide reduced thermal resistance for packaging of high voltage and high current power switching devices, e.g. comprising GaN HEMTs, SiC MOSFETs and Si IGBTs, which operate at elevated temperatures, e.g. for improved device performance and reliability.

### BRIEF DESCRIPTION OF THE DRAWINGS

FIG. 1A (Prior Art) shows 3D rendering of an example of an embedded die package comprising a E-mode lateral GaN HEMT device structure embedded in a laminated dielectric body with a bottom-side thermal pad;

FIGS. 1B and 1C show schematic top-side and bottom-side views of the embedded die package shown in FIG. 1A;

FIG. 2A (Prior Art) shows 3D rendering of an example of an embedded die package comprising a E-mode lateral GaN HEMT device structure embedded in a laminated dielectric body with a top-side thermal pad;

FIGS. 2B and 2C show schematic top-side and bottom-side views of the embedded die package shown in FIG. 2A.

FIG. 3A shows a 3D rendering of top-side and bottom-side views a dual-side cooled embedded die package of example embodiments;

FIGS. 3B and 3C show schematic top-side and bottom-side views of the embedded die package shown in FIG. 3A;

FIG. 4 shows a schematic top plan view of a semiconductor die comprising an E-mode lateral GaN HEMT of an example embodiment to illustrate a device topology with large area source and drain contact areas and dual gate contact areas;

FIG. 5 shows a plan view of the bottom side of a dual-side cooled embedded die package of a first example embodiment;

FIG. 6A shows a schematic cross-sectional view through plane A-A of FIG. 5 to illustrate the laminated multilayer structure of the dual-side cooled embedded die package of a first example embodiment;

FIG. 6B shows a schematic cross-sectional view through plane B-B of FIG. 5 to illustrate the laminated multilayer structure of the dual-side cooled embedded die package of a first example embodiment;

FIG. 6C shows a schematic cross-sectional view through plane A-A of FIG. 5 to illustrate the laminated multilayer structure of the dual-side cooled embedded die package of the first example embodiment mounted on a PCB substrate, with arrows to represent schematically the primary and secondary thermal paths;

FIG. 6D shows a schematic cross-sectional view through plane B-B of FIG. 5 to illustrate the laminated multilayer structure of the dual-side cooled embedded die package of the first example embodiment mounted on a PCB substrate, with arrows to represent schematically the primary and secondary thermal paths;

FIG. 7 shows a plan view of the bottom side of a dual-side cooled embedded die package of a second example embodiment;

FIG. 8A shows a schematic cross-sectional view through plane A-A of FIG. 5 to illustrate the laminated multilayer structure of the dual-side cooled embedded die package of the second example embodiment;

FIG. 8B shows a schematic cross-sectional view through plane B-B of FIG. 5 to illustrate the laminated multilayer structure of the dual-side cooled embedded die package of the second example embodiment;

FIG. 9 shows a schematic view of an overlay of metal layers and conductive vias for the layer stack of an embedded die package of the first or second embodiments;

FIG. 10 shows a plan view of the first conductive metal layer (Metal 1) which is provided by the leadframe of the first and second embodiments with a power semiconductor die mounted on the leadframe;

FIG. 11 shows a plan view of the second conductive metal layer (Metal 2) defining source, drain and gate metal;

FIG. 12 shows a plan view of the third conductive metal layer (Metal 3) defining the top-side thermal pad;

FIG. 13 shows a plan view of the bottom side external pads for the embedded die package of the first and second embodiments;

FIG. 14A shows an enlarged view of FIG. 9;

FIG. 14B shows a 3D rendering of an overlay of metal layers of the embedded die package of the first embodiment;

FIG. 15 shows a plan view of the bottom side of a dual-side cooled embedded die package of a third example embodiment;

FIG. 16A shows a schematic cross-sectional view through plane A-A of FIG. 15 to illustrate the laminated multilayer structure of the dual-side cooled embedded die package of the third example embodiment;

FIG. 16B shows a schematic cross-sectional view through plane B-B of FIG. 15 to illustrate the laminated multilayer structure of the dual-side cooled embedded die package of the third example embodiment;

FIG. 17 shows a plan view of the bottom side of a dual-side cooled embedded die package of a fourth example embodiment;

FIG. 18A shows a schematic cross-sectional view through plane A-A of FIG. 17 to illustrate the laminated multilayer structure of the dual-side cooled embedded die package of the fourth example embodiment;

FIG. 18B shows a schematic cross-sectional view through plane B-B of FIG. 17 to illustrate to illustrate the laminated multilayer structure of the dual-side cooled embedded die package of the fourth example embodiment;

FIG. 19 shows a plan view of the bottom side of a dual-side cooled embedded die package of a fifth example embodiment;

FIG. 20A shows a schematic cross-sectional view through plane A-A of FIG. 19 to illustrate the laminated multilayer structure of the dual-side cooled embedded die package of the fifth example embodiment;

FIG. 20B shows a schematic cross-sectional view through plane B-B of FIG. 19 to illustrate the laminated multilayer structure of the dual-side cooled embedded die package of the fifth example embodiment;

FIG. 21 shows a plan view of the bottom side of a dual-side cooled embedded die package of a sixth example embodiment;

FIG. 22A shows a schematic cross-sectional view through plane A-A of FIG. 21 to illustrate the laminated multilayer structure of the dual-side cooled embedded die package of the sixth example embodiment;

FIG. 22B shows a schematic cross-sectional view through plane B-B of FIG. 21 to illustrate the laminated multilayer structure of the dual-side cooled embedded die package of the sixth example embodiment;

FIG. 23 shows a plan view of the bottom side of a dual-side cooled embedded die package of a seventh example embodiment;

FIG. 24A shows a schematic cross-sectional view through plane A-A of FIG. 23 to illustrate the laminated multilayer structure of the dual-side cooled embedded die package of the seventh example embodiment;

FIG. 24B shows a schematic cross-sectional view through plane B-B of FIG. 23 to illustrate the laminated multilayer structure of the dual-side cooled embedded die package of the seventh example embodiment;

FIG. 25 shows a schematic cross-sectional view to illustrate the laminated multilayer structure of the dual-side cooled embedded die package of an eighth example embodiment;

FIG. 26 shows a schematic cross-sectional view to illustrate the laminated multilayer structure of the dual-side cooled embedded die package of a ninth example embodiment;

FIG. 27 shows a schematic thermal model for an example power module assembly comprising an embedded die package which is bottom-cool only;

FIG. 28 shows a schematic thermal model for an example power module assembly comprising an embedded die package which is top-cool only;

FIG. 29 shows a schematic thermal model for an example power module assembly comprising an embedded die package which is dual-side cool; and

FIG. 30 shows a table listing data comparing the thermal resistance of the three examples shown in FIGS. 27, 28 and 29.

The foregoing and other features, aspects and advantages of the present invention will become more apparent from the following detailed description, taken in conjunction with the accompanying drawings, of example embodiments of the invention, which description is by way of example only.

### DETAILED DESCRIPTION

For background information on packaging of power semiconductor devices, packaging solutions that offer low inductance interconnections are disclosed, for example, in the Applicant's earlier filed patent documents: U.S. patent application Ser. No. 15/027,012, filed Apr. 15, 2015, now U.S. Pat. No. 9,659,854, entitled “Embedded Packaging for Devices and Systems Comprising Lateral GaN Power Transistors”; U.S. patent application Ser. No. 15/064,750, filed Mar. 9, 2016, now U.S. Pat. No. 9,589,868, entitled “Packaging Solutions for Devices and Systems Comprising Lateral GaN Power Transistors”; U.S. patent application Ser. No. 15/064,955, filed Mar. 9, 2016, now U.S. Pat. No. 9,589,869, entitled “Packaging Solutions for Devices and Systems Comprising Lateral GaN Power Transistors”; and U.S. patent application Ser. No. 15/197,861, filed Jun. 30, 2016, now U.S. Pat. No. 9,824,949, entitled “Packaging Solutions for Devices and Systems Comprising Lateral GaN Power Transistors”.

As described herein, “embedded die packaging” refers to package structures in which a power semiconductor die, e.g. a GaN HEMT, is embedded in a dielectric package body, e.g.: a dielectric polymer resin composition, such as a plastic encapsulation material or a glass fiber epoxy composite, such as FR4 type materials, or a ceramic composite material. Conductive interconnects through the dielectric layers are provided e.g., by copper traces, posts and vias, that provide low inductance interconnections to external contact pads (lands) for source, drain and gate connections.

In some types of encapsulated packaging, the GaN die is embedded by overmolding or injection of a polymer dielectric material around the die and conductive interconnect materials.

In other types of embedded die packaging, for example, as described in U.S. patent application Ser. No. 16/298,305, entitled “Embedded Die Packaging for Power Semiconductor Devices” filed Jul. 14, 2020 (now U.S. Pat. No. 11,342,788), the body of the package is a laminated structure built-up from layers of dielectric and layers of conductive metal. This type of laminated embedded die packaging provides low parasitic inductance in a compact (i.e. small form factor) package for high voltage, high current GaN HEMTs. For example, a 100V, 90 A GaN e-HEMT (GS61008T) may be provided in a top-side cooled laminated package which is about 7 mm×4 mm, and 0.54 mm thick; a 650V, 60 A GaN e-HEMT (GS66516T) may be provided in a laminated package which is 9 mm×7.6 mm and thick.

The dielectric polymer resin composition forming laminated embedded die packaging may include laminate sheets and layers of composite material referred to as prepreg, which is a substrate material, such as woven or non-woven glass-fiber cloth, which is pre-impregnated with one or more polymer materials, such as a dielectric epoxy composition. The dielectric epoxy composition may comprise an epoxy resin, curing agents, additives, such as fire retardants, and fillers and other substances to modify properties of the resulting composite material. One or more pre-cured epoxy laminate sheets and/or uncured prepreg layers are cut to form a cavity for the semiconductor die, and sandwiched between other uncured prepreg layers, i.e. assembled as a layer stack (which may be referred to as a layup), and the layers are then bonded together in a press, e.g. in a curing process using heat and pressure, to form a laminated dielectric body of the package in which the semiconductor die is embedded.

For power semiconductor devices, a typical embedded die package comprises low inductance electrical interconnect layers and conductive vias, e.g. formed from plated copper, and a thermal pad, also formed from plated copper. The outer layers of an embedded package comprise an isolation layer which is a coating of a material that provides an electrically insulating and protective outer covering over the underlying dielectric and conductive layers, e.g. the outer dielectric layer covers underlying layers including copper source, drain and gate interconnect traces, and openings are provided in the outer dielectric layer for the external source, drain and gate contact areas, and for the thermal pad.

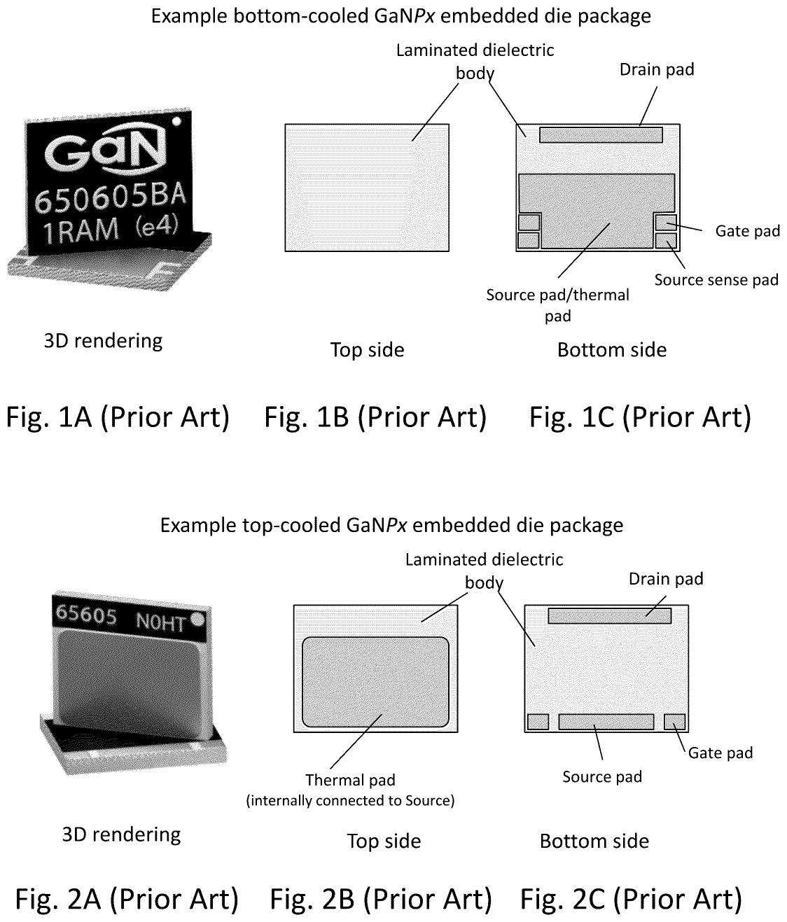

Examples of embedded die packaging device structures comprising a laminated dielectric body containing a lateral GaN power transistor are shown schematically in FIGS. 1A, 1B and 1C and FIGS. 2A, 2B and 2C. FIG. 1A shows top-side and bottom-side 3D views of a first example of a package comprising an embedded GaN-on-Si die comprising a 650V lateral GaN e-HEMT. As shown in FIG. 1B, the top-side of the package comprises an exposed layer of dielectric of the laminated dielectric body, and as shown in FIG. 1C, the bottom side of the package comprises a source pad/thermal pad, a drain pad, and source sense and gate contact pads. This type of package, where the electrical contact pads and thermal pad are provided on the same side of the package is referred to as a bottom-side cooled embedded package, or B-type embedded die package. FIG. 2A shows top-side and bottom-side 3D views of another example of a package comprising an embedded GaN-on-Si die comprising a lateral GaN e-HEMT. As shown in FIG. 2B, the top-side of the package comprises a thermal pad, which is internally connected to source. As shown in FIG. 2C, the source, drain and gate contact pads are provided on a bottom-side of the package. This type of package, where the electrical contact pads are provided on one side of the package and the thermal pad is provided on the opposite side, is referred to as a top-side cooled embedded package, or T-type embedded die package.

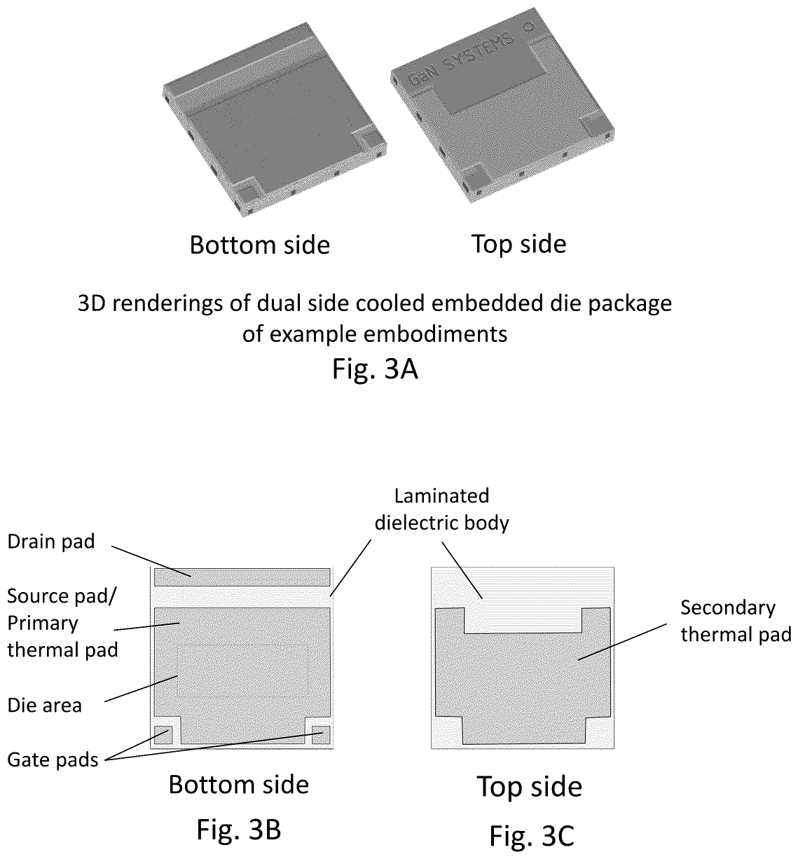

FIG. 3A show views of 3D renderings of the bottom side and top side of an embedded die package of example embodiments comprising a laminated dielectric body and primary and secondary thermal pads for dual-side cooling. FIG. 3B shows a schematic plan view of the bottom side, comprising a source pad, which is also the primary thermal pad, a drain pad and gate pads. FIG. 3C shows a schematic plan view of the top side, comprising the secondary thermal pad.

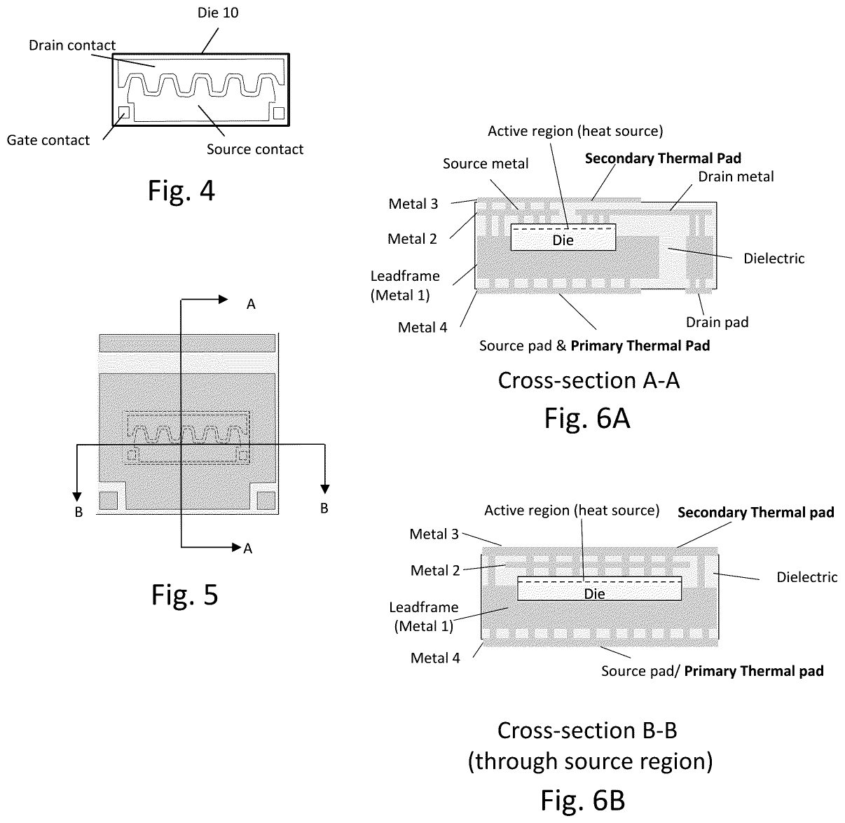

FIG. 4 shows a schematic top plan view of an example power semiconductor die comprising a lateral GaN power transistor, wherein the die comprises a thick copper redistribution layer (RDL), which defines large area source and drain contact areas (source pad and drain pad) and dual gate contact areas (gate pads), on the top side (active side) of the die.

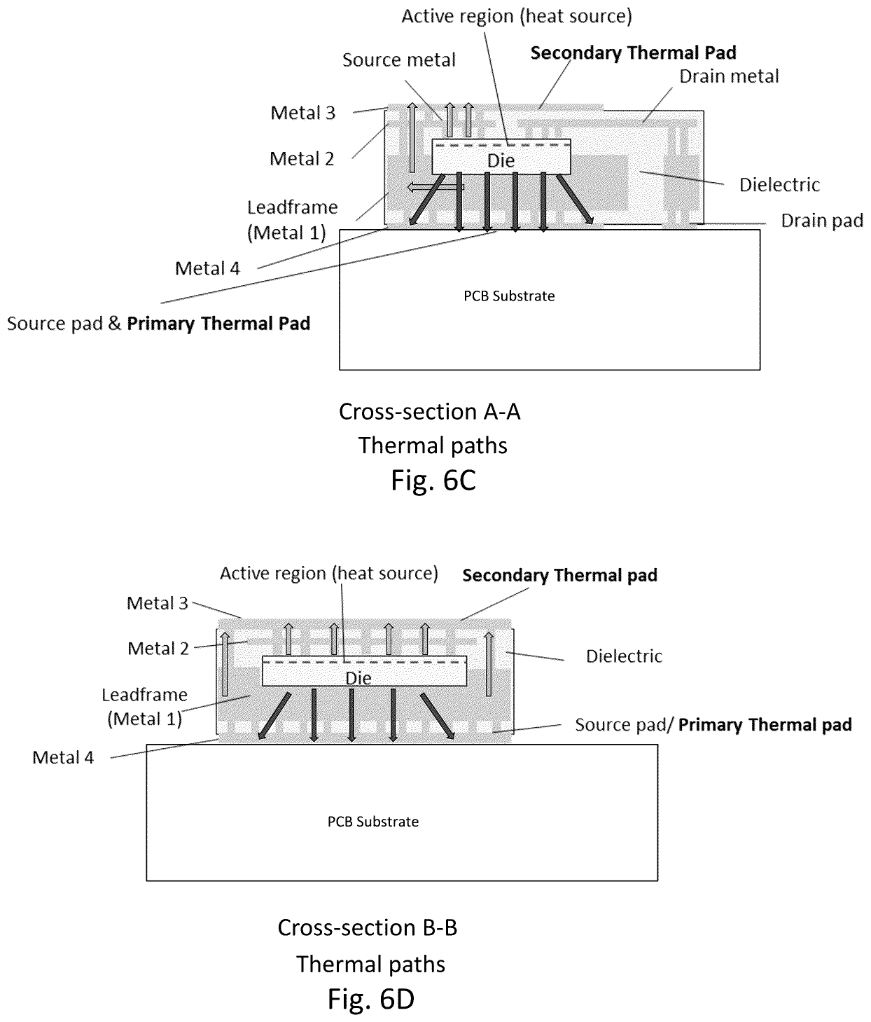

FIG. 5 shows a schematic plan view of an embedded die package of a first example embodiment. The internal position of the embedded die is shown in dotted outline. As an example, the outline of the package may be square or rectangular, e.g. having external dimensions of ˜10 mm×˜10 mm or ˜5 mm×˜10 mm. FIGS. 6A and 6B show schematic cross-sectional views through sections A-A and B-B respectively of FIG. 5 to illustrate the internal layer structure. The embedded die package comprises a laminated dielectric body comprising an epoxy composition fabricated from laminations comprising several epoxy laminate and prepreg layers (light green) and conductive copper layers (copper color). In this embodiment, there are four conductive metal layers (Metal 1, Metal 2, Metal 3 and Metal 4). The die is mounted on a leadframe (metal 1). The active region of the die (front or top-side of the die) is facing upwards in this view, and the back-side of the die is attached in thermal contact with the leadframe. Metal 2 is patterned to define source and drain connections (source metal and drain metal), and gate connections (not shown in this view). Metal 4 defines a source pad which is also a primary thermal pad. Metal 3 defines a secondary thermal pad. Electrical and thermal interconnections between metals layers 1, 2, 3 and 4 are provided by electrically conductive vias and thermally conductive vias. For example, these components may comprise low inductance conductive copper interconnects comprising copper filled vias or copper filled micro-vias. Copper filled thermal vias provide thermal contact between the leadframe and the primary thermal pad on the bottom side of the package. Plated copper layers provide the external source, drain and gate pads on a bottom-side of the package, and the secondary thermal pad on the top-side of the package. External surfaces of the source, drain and gate pads and thermal pads may be provided with a plating of e.g. nickel and gold, to facilitate surface mounting, e.g. by soldering, or other processing. The embedded die structure shown in FIGS. 6A and 6B may referred to as a symmetric layup because there four metal layers, wherein two metal layers are provided on each side of the die

In FIGS. 5, 6A and 6B, as in other Figures, it will be appreciated that layer thicknesses and lateral dimensions are shown schematically, and are not drawn to scale; the lateral patterning of shapes of the metal layers are shown as rectangular shapes, by way of example only. For example, in the plan view of FIG. 5, in practice, internal and external corners of the source, drain and gate contact areas may be 90 degrees as shown schematically, or radiused to avoid sharp corners.

FIGS. 6C and 6D illustrate schematically the embedded die package of the first embodiment surface mounted on a PCB substrate. The attachment of the package to the PCB substrate may use any suitable surface mount technology, such as soldering. As in a conventional embedded die package comprising a bottom-side thermal pad, the primary thermal path is through the die substrate, through the leadframe to the bottom-side thermal path, as illustrated schematically by the red arrows in the cross-sectional views shown in FIGS. 6C and 6D. The top-side, secondary thermal pad provides a secondary thermal path for thermal dissipation from the top-side of the die, wherein the active region is a heat source, as illustrated schematically by the yellow arrows. In a power module assembly, the PCB may be mounted on a thermally conductive substrate comprising a heatsink which is actively or passively cooled. A secondary heatsink may be provided on the secondary thermal pad (e.g. see examples of power module assemblies illustrated schematically in FIG. 29)

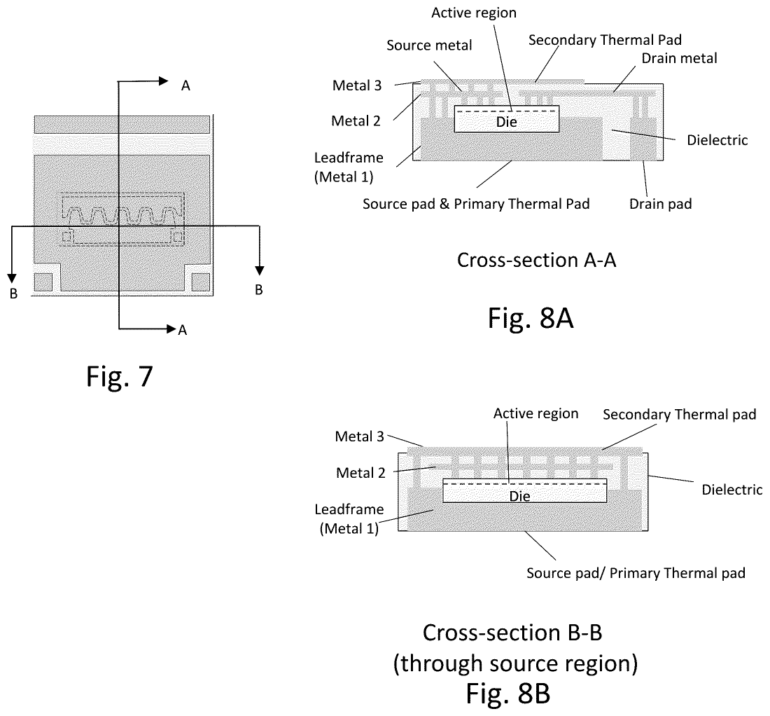

FIG. 7 shows a schematic plan view of an embedded die package of a second example embodiment. FIGS. 8A and 8B show schematic cross-sectional views through sections A-A and B-B respectively through FIG. 7 to illustrate the internal layer structure. The embedded die package comprises a laminated dielectric body comprising an epoxy composition fabricated from laminations comprising several epoxy laminate and prepreg layers (light green) and conductive copper layers (copper color). In this embodiment, there are three conductive metal layers Metal 1, Metal 2, Metal 3. The die is mounted on a leadframe provided by metal 1. The active region of the die (front or top-side of the die) is facing upwards in this view, and the back-side of the die is attached in thermal contact with the leadframe. Metal 2 is patterned to define source and drain connections (source metal and drain metal) and gate connections (not shown in this view). Compared to the embedded die package of the first embodiment, in the embedded die package of the second embodiment, the exposed surface of leadframe itself provides the primary thermal pad and bottom-side external source pad. (That is, Metal 4 of the first embodiment is omitted). Electrical and thermal interconnections between metal layers 1, 2 are 3 are provided by electrically conductive vias and thermally conductive vias. For example, these components may comprise low inductance conductive copper interconnects comprising copper filled vias or copper filled micro-vias. Copper filled thermal vias provide thermal contact between the leadframe and the primary thermal pad on the bottom side of the package. Plated copper layers provide the external source, drain and gate pads on a bottom-side of the package, and the secondary thermal pad on the top-side of the package. The embedded die structure shown in FIGS. 8A and 8B may referred to as an asymmetric layup because there is one metal layer (leadframe-Metal 1) provided on the bottom-side of the die and two metal layers (Metal 2, Metal 3) provided on the top-side of the die.

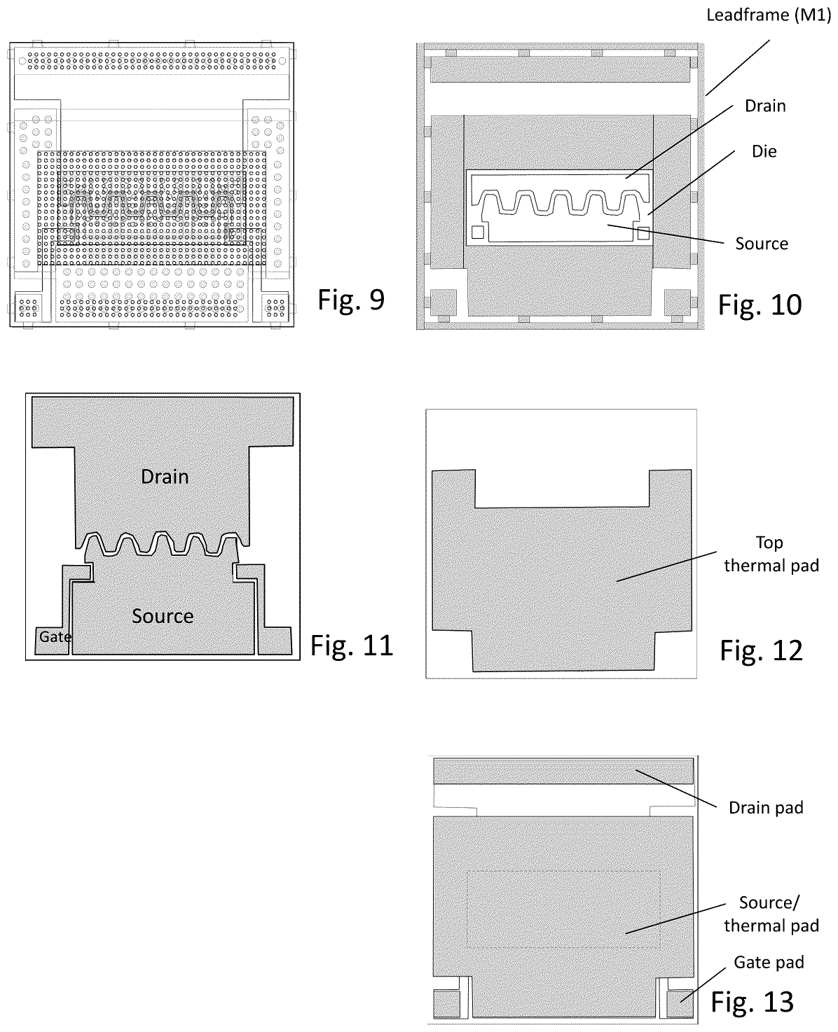

FIG. 9 shows a schematic plan view comprising an overlay of the metal layers of the embedded die package of the first embodiment to illustrate patterning of the conductive metal layers (Metal 1, Metal 2, Metal 3 and Metal 4, and layout of thermally conductive vias and electrically conductive vias. FIG. 10 shows a schematic plan view of the leadframe (metal 1) showing the die mounted on the leadframe. FIG. 11 shows a schematic plan view of metal 2, which is patterned to define large area source metal and drain metal interconnect areas and gate metal interconnect areas. FIG. 12 shows a schematic top-side plan view of the secondary thermal pad formed by metal 3. FIG. 13 shows a schematic bottom-side plan view of metal 4, which provided the primary thermal pad/source pad, drain pad, and gate pads. For the embedded die package of the second embodiment, where metal 4 is omitted, a schematic bottom-side plan view of metal 1 (leadframe), which provides the primary thermal pad/source pad, drain pad, and gate pads would have the same pattern as shown in FIG. 13

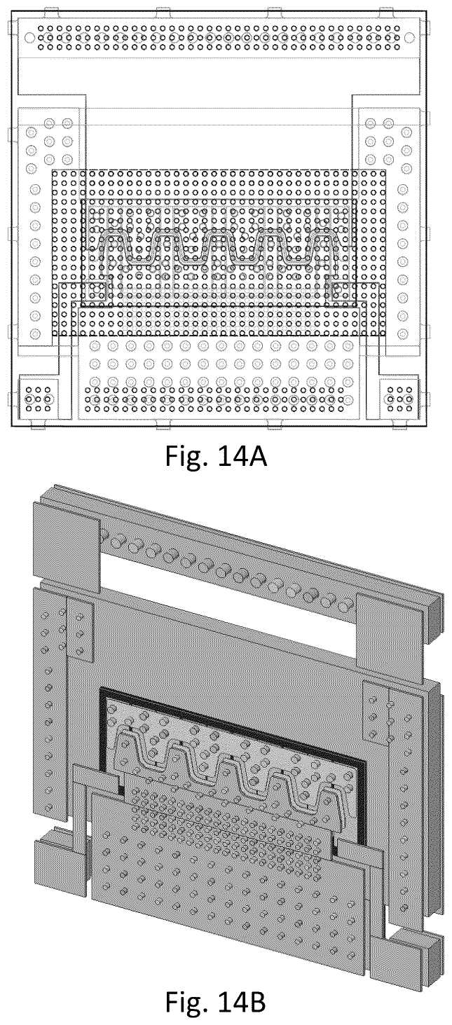

FIG. 14A shows an enlarged view of FIG. 9. FIG. 14B shows a 3D rendering of some of the metal layers and conductive vias of FIG. 14A, with dielectric layers omitted for simplicity/clarity.

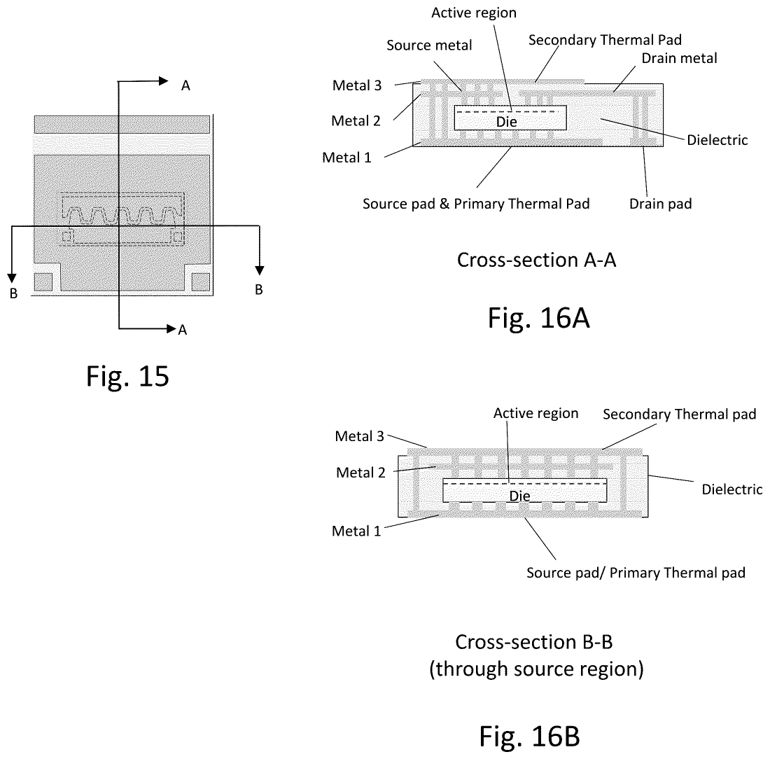

FIG. 15 shows a schematic plan view of an embedded die package of a third example embodiment. FIGS. 16A and 16B show schematic cross-sectional views through sections A-A and B-B respectively of FIG. 15 to illustrate the internal layer structure. The embedded die package comprises a laminated dielectric body comprising an epoxy composition fabricated from laminations comprising several epoxy laminate and prepreg layers (light green) and conductive copper layers (copper color). In this embodiment, a leadframe is not provided. For example, the dielectric layers (light green) comprise a core of a glass-fiber reinforced FR4 epoxy dielectric layer and upper and lower fiber reinforced dielectric layers, which may be referred to as dielectric build-up layers, e.g. formed from an FR4 type epoxy prepreg. The top and bottom conductive layers are plated copper layers which are interconnected with plated copper filled conductive vias and micro-vias (copper color). The primary and secondary thermal pads and thermal vias are also formed from plated copper. In this embodiment, there are three conductive metal layers Metal 1, Metal 2, Metal 3. Metal 1 is patterned to define the source pad and primary thermal pad, a drain pad, and gate a pad (not shown). The active region of the die (front or top-side of the die) is facing upwards in this view. Metal 2 is patterned to define source and drain connections (source metal and drain metal) and gate connections (not shown in this view). Metal 3 is patterned to define a secondary thermal pad. For example, these components may comprise low inductance conductive copper interconnects comprising copper filled vias or copper filled micro-vias. Copper filled thermal vias provide thermal contact between the die and the primary thermal pad (Metal 1) on the bottom side of the package. Plated copper layers provide the external source, drain and gate pads on a bottom-side of the package, and the secondary thermal pad on the top-side of the package. External surfaces of the source, drain and gate pads and thermal pads may be provided with a plating of e.g. nickel and gold. The embedded die structure shown in FIGS. 16A and 16B may referred to as an asymmetric layup because there is one metal layer (Metal 1) provided on the bottom-side of the die and two metal layers (Metal 2, Metal 3) provided on the top-side of the die.

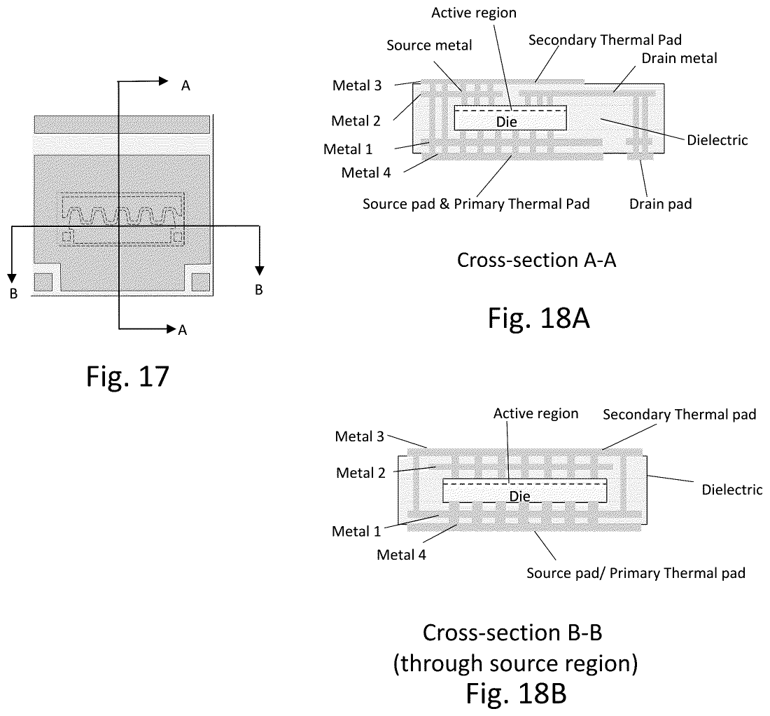

FIG. 17 shows a schematic plan view of an embedded die package of a fourth example embodiment. FIGS. 18A and 18B show schematic cross-sectional views through sections A-A and B-B respectively of FIG. 17 to illustrate the internal layer structure. This embodiment is an example of a symmetric layup comprising four metal layers (Metal 1, Metal 2, Metal 3 and Metal 4), where two metal layers are provided on each side of the die. It differs from the third embodiment in that a fourth metal layer is provided on the bottom-side. The embedded die package comprises a laminated dielectric body comprising an epoxy composition fabricated from laminations comprising several epoxy laminate and prepreg layers (light green) and conductive copper layers (copper color). In this embodiment, a leadframe is not provided. For example, the dielectric layers comprise a core of a glass-fiber reinforced FR4 epoxy dielectric layer and upper and lower fiber reinforced dielectric layers, e.g. build-up layers formed from an FR4 type epoxy prepreg. The top and bottom conductive layers are plated copper interconnect layers which are interconnected with plated copper filled conductive vias and micro-vias (copper color). The primary and secondary thermal pads and thermal vias are also formed from plated copper. In this embodiment, there are four conductive metal layers (Metal 1, Metal 2, Metal 3, Metal 4. Metal 1 and metal 4 are patterned to define the source pad and primary thermal pad, a drain pad, and gate pad (not shown), and the thermal pads provided metal 1 and metal 4 are interconnected by thermal vias. The active region of the die (front or top-side of the die) is facing upwards in this view. Metal 2 is patterned to define source and drain connections (source metal and drain metal) and gate connections (not shown in this view). Metal 3 is patterned to define a secondary thermal pad. For example, these components may comprise low inductance conductive copper interconnects comprising copper filled vias or copper filled micro-vias. Copper filled thermal vias provide thermal contact between the die and the primary thermal pad (provided by Metal 1 and Metal 4) on the bottom side of the package. Plated copper layers provide the external source, drain and gate pads on a bottom-side of the package, and the secondary thermal pad on the top-side of the package.

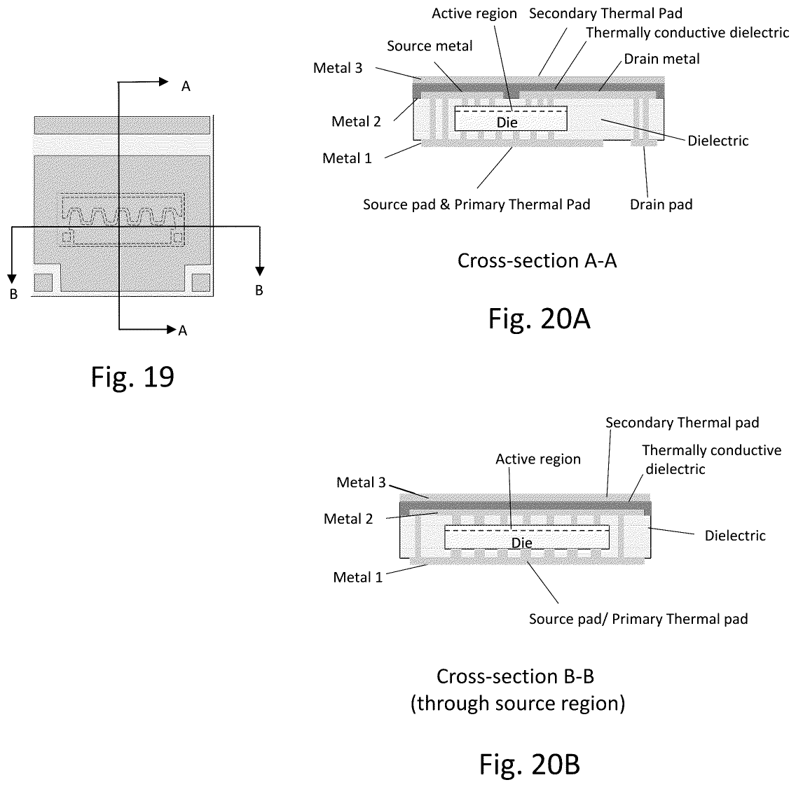

FIG. 19 shows a schematic plan view of an embedded die package of a fifth example embodiment. FIGS. 20A and 20B show schematic cross-sectional views through sections A-A and B-B respectively of FIG. 19 to illustrate the internal layer structure. The embedded die package comprises a laminated dielectric body (light green) comprising an epoxy composition fabricated from laminations comprising several epoxy laminate and prepreg layers and conductive copper layers (copper color). In this embodiment, a leadframe is not provided. For example, the dielectric layers comprise a core of a glass-fiber reinforced FR4 epoxy dielectric layer and upper and lower fiber reinforced dielectric layers, e.g. dielectric build-up layers formed from a FR4 type epoxy prepreg. The top and bottom conductive layers are plated copper interconnect layers which are interconnected with plated copper filled conductive vias and micro-vias (copper color). The primary and secondary thermal pads and thermal vias are also formed from plated copper. In this embodiment, there are three conductive metal layers Metal 1, Metal 2, and Metal 3. Metal 1 is patterned to define the source pad and primary thermal pad, a drain pad, and gate pad (not shown). The active region of the die (front or top-side of the die) is facing upwards in this view. Metal 2 is patterned to define source and drain connections (source metal and drain metal) and gate connections (not shown in this view). A top thermal pad is provided by the top metal layer, metal 3. In this embodiment, a layer of thermally conductive dielectric provides a thermal path between metal 2 and metal 3. Thermal vias between metal 2 and metal 3 are not provided.

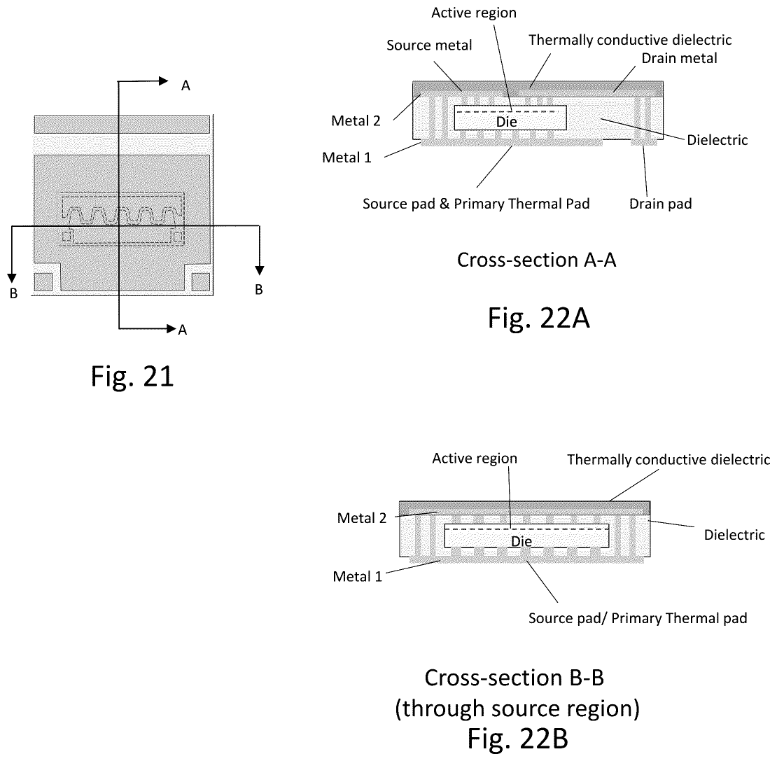

FIG. 21 shows a schematic plan view of an embedded die package of a sixth example embodiment. FIGS. 22A and 22B show schematic cross-sectional views through sections A-A and B-B respectively of FIG. 21 to illustrate the internal layer structure. The embedded die package comprises a laminated dielectric body comprising an epoxy composition fabricated from laminations comprising several epoxy laminate and prepreg layers (light green) and conductive copper layers (copper coloured). In this embodiment, a leadframe is not provided. For example, the dielectric layers comprise a core of a glass-fiber reinforced FR4 epoxy dielectric layer and upper and lower fiber reinforced dielectric layers, e.g. formed from FR4 epoxy prepreg. The top and bottom conductive layers are plated copper interconnect layers which are interconnected with plated copper filled conductive vias and micro-vias (copper coloured). The primary and secondary thermal pads and thermal vias are also formed from plated copper. In this embodiment, there are only two conductive metal layers Metal 1 and Metal 2. Metal 1 is patterned to define the source pad and primary thermal pad, a drain pad, and gate pad (not shown). The active region of the die (front or top-side of the die) is facing upwards in this view. Metal 2 is patterned to define source and drain connections (source metal and drain metal) and gate connections (not shown in this view). A layer of thermally conductive dielectric is provided to isolate metal 2 from the external surface of the package, and this layer of thermally conductive dielectric also provides a secondary thermal path for top cooling of the package; this arrangement may be referred to as a “pseudo top-cool” package. For example, these conductive interconnect components may comprise low inductance conductive copper interconnects comprising copper filled vias or copper filled micro-vias. Copper filled thermal vias provide thermal contact between the die and the primary thermal pad (Metal 1) on the bottom side of the package. Plated copper layers provide the external source/thermal pad, drain pad and gate pad on the bottom-side of the package.

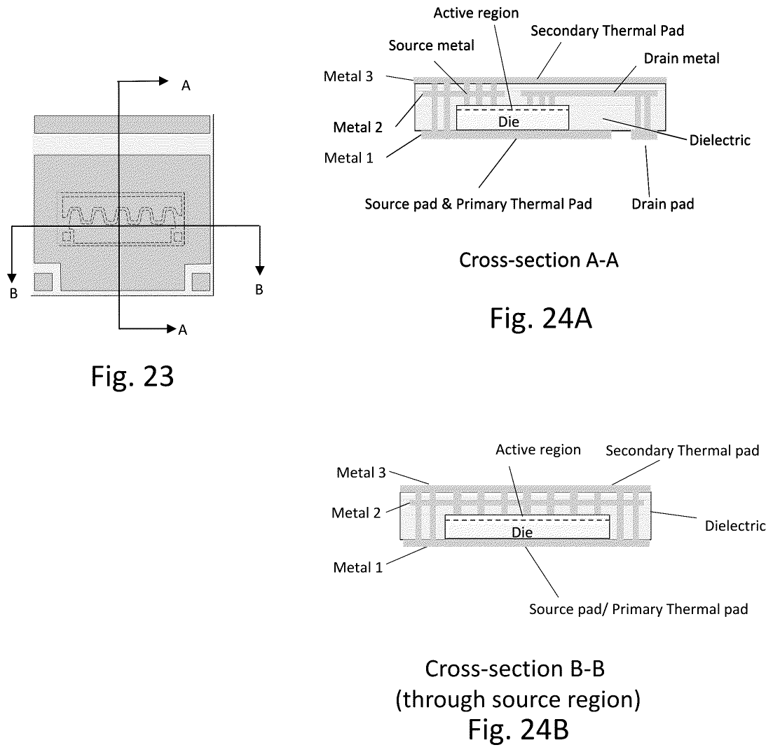

FIG. 23 shows a schematic plan view of an embedded die package of a seventh example embodiment. FIGS. 24A and 24B show schematic cross-sectional views through sections A-A and B-B respectively to illustrate the internal layer structure. The embedded die package comprises a laminated dielectric body comprising an epoxy composition fabricated from laminations comprising several epoxy laminate and prepreg layers (light green) and conductive copper layers (copper coloured). In this embodiment, a leadframe is not provided. The die is mounted directly on a conductive metal substrate layer Metal 1. Otherwise, elements of the embedded die package of this embodiment are the same as that shown in FIGS. 15, 16A and 16B.

The embedded die packages of the first to fourth example embodiments are based on laminated structures formed with or without a leadframe, wherein the primary thermal pad is provided on the bottom and a secondary thermal pad is provided on the top. These example embodiments show layer stacks (layups) comprising 3 or 4 metal layers. In variants of these layups, the multilayer laminated body of the embedded die package may comprise additional metal layers and dielectric layers, in which the metal layers are interconnected by electrically conductive vias to form source, drain and gate connections and thermally conductive vias are provided to interconnect multiple metal layers that form the top and bottom thermal pads.

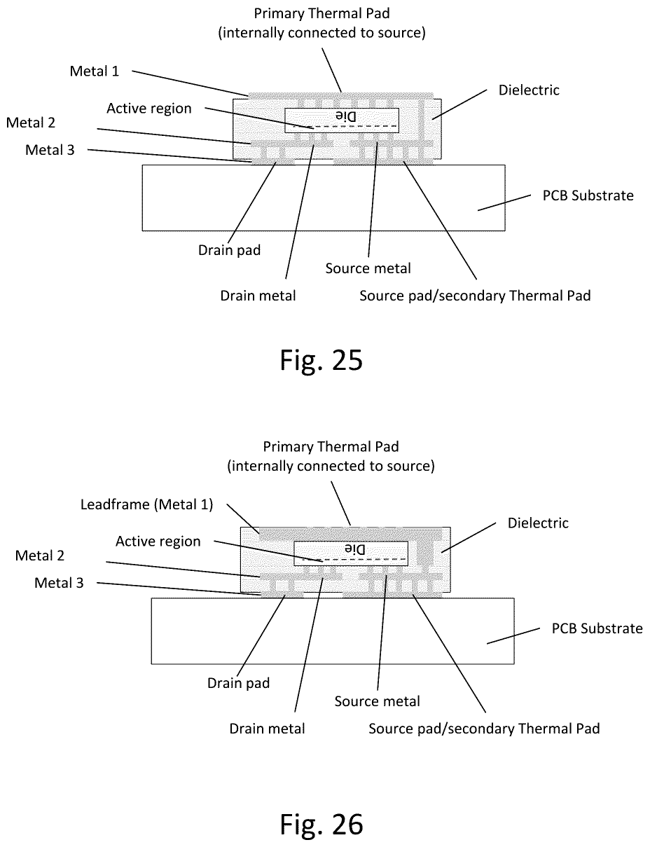

FIG. 25 shows a schematic cross-sectional view to illustrate the internal layer structure of an embedded die package of an eighth embodiment. The embedded die package comprises a laminated dielectric body comprising an epoxy composition fabricated from laminations comprising several epoxy laminate and prepreg layers (light green) and conductive copper layers (copper color), based on a conventional top-cool structure wherein the primary thermal pad is provided on the top side, internally connected to source, and the source and drain connections are made of the active side of the die. The source pad on the bottom side is extended to form a secondary thermal pad. It will be appreciated that variants of this embodiment may be fabricated with a leadframe, without a leadframe, and with different numbers of metal layers, to provide symmetric and asymmetric layups, e.g. as described with references to the embedded die packages of the previously described embodiments. For example, FIG. 26 shows a schematic cross-sectional diagram of an embedded die package comprising a leadframe, wherein the leadframe forms the top side primary thermal pad. A secondary thermal pad is provided on the bottom side by extending the source contact area, similar to that shown in FIG. 25.

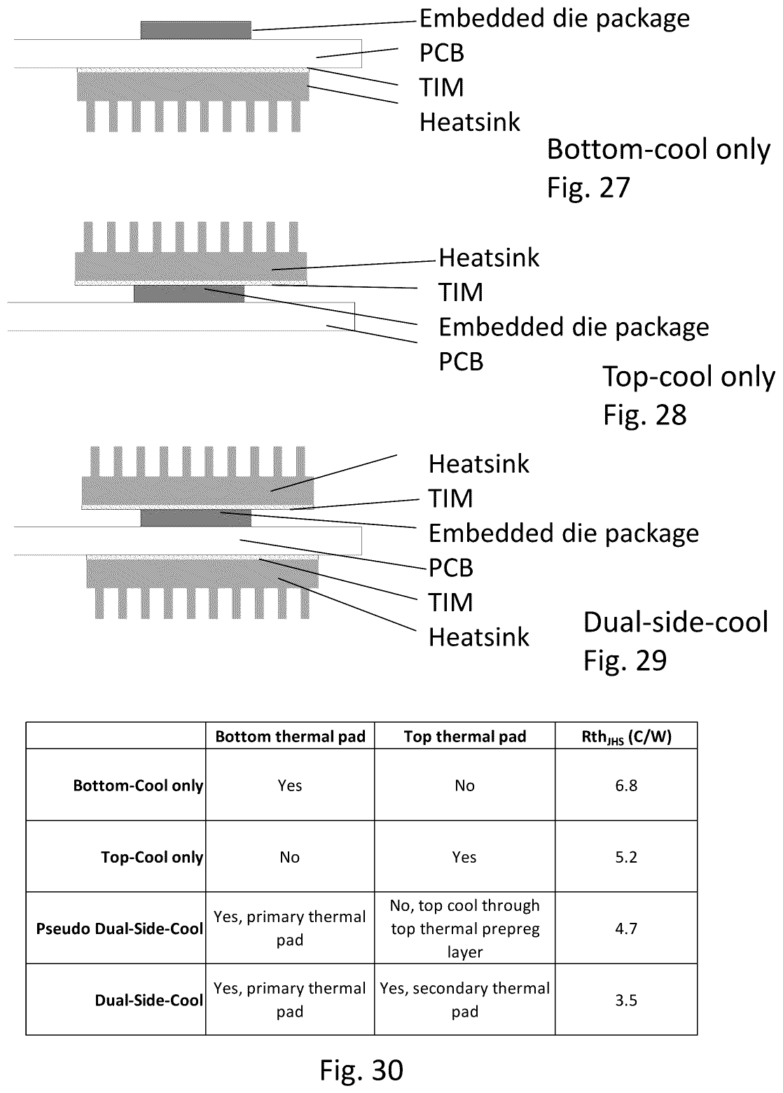

FIGS. 27, 28 and 29 show schematic diagrams to represent thermal models for embedded die packaging which are bottom-cooled only, top-cooled only and dual-side cooled. FIG. 27 shows schematically a bottom-cooled embedded die package mounted on a PCB, wherein the PCB is mounted on a heatsink with an intervening layer of thermal interface material (TIM). FIG. 28 shows schematically a top-cooled embedded die package mounted on a PCB, wherein a heatsink is mounted on the embedded die package with an intervening layer of TIM. FIG. 29 shows schematically a dual-side cooled embedded die package mounted on a PCB, wherein the PCB is mounted on a primary heatsink with an intervening layer of TIM and a secondary heatsink is mounted on top of the embedded die package with an intervening layer of TIM.

FIG. 30 compares thermal modelling data for the junction to heatsink thermal resistance Rth_{JHS} (C/W) for example assemblies of embedded die packages comprising bottom-cool only, top-cool only, pseudo-dual side cool, and dual-side cool with primary and secondary thermal pads. The example thermal model for a dual-side-cooled assembly based on a headframe type embedded die package of a structure based on the embedded die package of the first embodiment described above. The pseudo-dual-side cooled embedded die package is modelled by removing the secondary thermal pad, and increasing the thickness of the prepreg layer to keep the package thickness the same. Based on these examples, the thermal resistance of dual-side-cooled embedded die package is reduced significantly (Rth_{JHS} 3.5 C/W) compared to a top-side-cooled only (Rth_{JHS} 5.2 C/W) and bottom-side-cooled only (Rth_{JHS} 6.8 C/W). The pseudo-dual side cooled assembly provides some improvement ((Rth_{JHS} 4.7 C/W). The dual-side-cooled package offers better thermal performance, e.g. >40% reduction in thermal resistance, compared to a conventional bottom-cooled package of comparable structure and dimensions. A lower Rth_{JHS} enables higher power density for the same maximum junction temperature Tⱼₘₐₓ, or provides a lower junction temperature Tj, which means reduced device loss, and improved reliability, e.g. lower risk of thermal runaway and improved lifetime.

Dual-side-cooled embedded die packaging of example embodiments has been described in detail, wherein the power semiconductor device comprises a GaN power switching device such as a high voltage, high current lateral GaN power transistor, e.g. a GaN HEMT, rated for high voltage and high current operation at an elevated temperature.

While embodiments of embedded die packaging for a power semiconductor device are described in detail with refer to a power semiconductor device comprising a GaN power transistor, a power semiconductor device may comprise a GaN diode. The power semiconductor device may comprise a plurality of GaN power transistors, a plurality GaN power diode, a combination of at least one GaN power transistor and at least one power diode. For example, the die may comprise a power semiconductor device which comprises a plurality of GaN transistors configured as one of: a half-bridge, a full-bridge, and other switching topologies. The die may comprise other components, integrated with the power semiconductor device, e.g., one or more of driver circuitry, control circuitry, sensors, passive components, et al., The power semiconductor device may be co-packaged and interconnected with other components, such as a driver chip, embedded in the package.

Embedded die packages of exemplary embodiments are described herein, wherein the power semiconductor device comprises a GaN power transistor device, such as at least one high voltage, high current GaN HEMT, which is described as having first and second contact areas which are referred to as source and drain contact area, and a third contact area which is described at a gate contact area. Embedded die packing of these embodiments are also applicable for embedded die packaging of GaN power diodes, in which the first and second contact areas would be referred to as anode and cathode contact areas, instead of source and drain contact areas. For example, for power semiconductor devices comprising lateral GaN HEMTs and GaN power diodes rated for, e.g. 100V or 650V operation, and for currents in a range of e.g. 20 A to ≥100 A, dielectric regions between source and drain contact areas of GaN HEMTS, or between anode and cathode contact areas of power diodes, which are provided on a front-side of the die, are subject to significant electric fields during operation. Additional build-up dielectric layers isolating these power areas of the die provides for improved reliability.

It is contemplated that in other example embodiments of embedded die packaging wherein the laminated dielectric body (layup) comprises additional dielectric buildup layers isolating contact areas in regions subject to e.g. high electric fields, or thermal cycling, during operation may also be more generally applicable to other semiconductor devices, where higher reliability embedded die packaging is required, because external coatings of solder resist can then be eliminated.

For example, the power semiconductor device may comprise another type of power transistor, e.g. a SiC MOSFET or a Si IGBT, or another type of power diode. For example, the power semiconductor device may comprise at least one power transistor, at least one power diode, a combination of at least one power transistor and at least one power diode, fabricated using GaN technology or other III-Nitride technology, or Si technology or SiC technology or other Group IV semiconductor technology, or other semiconductor technology applicable to power semiconductor devices.

Examples of suitable dielectric materials for the core and build-up layers of the laminated package body are described in related patent applications cited herein. For example, the at least one dielectric layer of the core and said first, second and outer dielectric build-up layers comprise any one of: a glass-fiber reinforced resin composition; a glass-fiber reinforced epoxy resin composition; a dielectric resin build-up layer; a dielectric epoxy build-up layer; a build-up layer which is formed from an ABF (Ajinimoto Build-up Film); and a combination thereof. The dielectric build-up layer may be a vacuum laminated dielectric. For example, a vacuum laminated reinforced dielectric underlying the solder resist may be formed from an epoxy prepreg or a sheet of an epoxy resin composition comprising filler particles, known as a BUF (build-up film).

The laminated body may comprise a layer stack which is symmetric or asymmetric, and is configured with a top-side and a bottom side thermal pad. The core of the laminated body may optionally comprise a leadframe, e.g. a copper leadframe, supporting the die. The core and dielectric build-up layers may comprise a dielectric epoxy composition having an FR4 epoxy composition, such as Panasonic R1577 or Hitachi E679 or other composition having similar electrical and mechanical characteristics. The dielectric build-up layers may comprise a BUF polymer composition such as Sekishi NX04H, N!07, NQ07X or NR10.

In exemplary embodiments, the conductive metallization layers of the embedded die packaging are described as comprising copper, e.g. plated copper. In other embodiments, any suitable metal, for example Cu, Al, Ni, Sn, Au, Ag, Pt, Pd, and an alloy of one or more of these metals, compatible with the selected semiconductor technology, may be used. Each of the metallization layers defining contact areas and interconnect traces may comprise a single layer or a plurality of layers of conductive materials.

More generally, for example, the power semiconductor device may comprise one of: a power transistor, a power diode, and a combination of a power transistor and a power diode. The power semiconductor device may comprise one or a plurality of transistors, one or a plurality of diodes, a combination of at least one transistor and at least one diode. For example, the power semiconductor device may comprise a plurality of power transistor switches configured as a half-bridge, full-bridge, or other switch topology. The power transistor switches may be integrated on a single die, or configured by embedding multiple die in an embedded die package. A power semiconductor device such as a transistor device or power diode device, or power switching device, may comprise other components, e.g. integrated driver and/or control circuitry, sensors, and/or other active or passive components.

For example, where the power semiconductor switching device comprises at least high voltage, high current lateral power transistor, such as a GaN HEMT, a SiC MOSFET or a Si IGBT rated for high voltage operation at an elevated temperature, an additional layer of dielectric isolates interconnect areas, e.g. source and drain contact areas, in regions subject to high electric field during operation. The power semiconductor device may be power diode, such as a GaN, SiC or Si diode. The die may comprise other components, e.g. driver and/or control circuitry integrated with the power semiconductor device, or the power semiconductor device may be co-packaged with other components embedded in the package. Where the power semiconductor device comprises a plurality of power transistors, these may be configured as a half-bridge, full-bridge, or other switching topologies.

The embedded die package may be configured for a die comprising a power semiconductor device which is e.g. a lateral GaN power transistor, or a SiC MOSFET or a Si IGBT, or a diode. For example, the power semiconductor transistor may be a high voltage, high current lateral GaN HEMT rated for operation at ≥100V or ≥600V and for a current of tens of Amps to hundreds of Amps, and rated for operation at a temperature ≥75 C or ≥100 C.

In the forgoing description, any references to color elements in the drawings refer to the color version of the drawings, i.e. the drawings that were submitted as non-black and white line drawings, and stored for access as supplemental material in the USPTO SCORE database.

Although embodiments of the invention have been described and illustrated in detail, it is to be clearly understood that the same is by way of illustration and example only and not to be taken by way of limitation, the scope of the present invention being limited only by the appended claims.

1. An embedded die package comprising a laminated body and a die comprising a power semiconductor device, the die being embedded within the laminated body, the laminated body comprising a stack of a plurality of dielectric build-up layers and a plurality of electrically conductive layers, wherein a primary thermal pad is provided on a first side of the package and a secondary thermal pad is provided on an opposite side of the package, the primary and secondary thermal pads providing for dual-side-cooling.

2. The embedded die package of claim 1, wherein the laminated body is based on a bottom-side-cooled layup that provides the primary thermal pad and electrical connections for the power semiconductor device on the first side (bottom-side) of the package and wherein the secondary thermal pad is provided on the opposite side (top-side) of the package.

3. The embedded die package of claim 1, wherein the laminated body is based on a top-side cooled layup that provides the primary thermal pad on the first side (top-side) of the package and wherein the secondary thermal pad and electrical connections for the power semiconductor device are provided on the opposite side (bottom-side) of the package.

4. The embedded die package of claim 2, wherein one of said plurality of electrically conductive layers comprises a leadframe, the leadframe supporting the die within the laminated body and providing said primary thermal pad.

5. The embedded die package of claim 3, wherein one of said plurality of electrically conductive layers comprises a leadframe, the leadframe supporting the die within the laminated body and providing said primary thermal pad.

6. An embedded die package comprising a laminated body and a die comprising a power semiconductor device, the die being embedded within the laminated body, wherein:
the die comprises a patterned layer of conductive metallization on a front-side (active-side) of the die providing electrical contact areas of the semiconductor power device, and a thermal contact area on a back-side of the die; and
a layer stack of the laminated body comprises:
a core comprising at least one dielectric layer which embeds the die;
at least first, second and third conductive metal layers which are separated by intervening dielectric layers of the layer stack;
the first conductive metal layer providing a first thermal pad which is in thermal contact with the thermal contact area on the back-side of the die;
the second conductive metal layer being patterned to define internal electrical interconnect areas; the internal electrical interconnect areas of the second conductive layer being connected by electrically conductive vias to respective electrical contact areas on the front-side of the die; and
the third conductive metal layer providing a second thermal pad overlying at least part of the second conductive metal layer;
external electrical contact areas of the power semiconductor device provided on a bottom-side of the package, respective internal electrical contact areas and external electrical contact areas being interconnected; and
wherein the first and second thermal pads provide for dual-side cooling.

7. The embedded die package of claim 6, wherein thermal vias provide for said thermal contact between the first thermal pad and the thermal contact on the back-side of the die.

8. The embedded die package of claim 6, comprising a fourth conductive layer underlying the first conductive layer, the fourth conductive layer forming an external thermal pad which is in thermal contact with the first thermal pad of the first conductive layer.

9. The embedded die package of claim 8, wherein thermally conductive vias provide said thermal contact between the first thermal pad and the external thermal pad.

10. The embedded die package of claim 6, wherein the first conductive layer comprises a leadframe supporting the die, and wherein said first thermal pad is provided by an exposed surface of the leadframe.

11. The embedded die package of claim 8, wherein the first conductive layer comprises a leadframe supporting the die.

12. The embedded die package of claim 6, wherein the power semiconductor device comprises a lateral power transistor, wherein said electrical contact areas of the power semiconductor device comprise electrical contact areas for a source, drain and gate of the lateral power transistor on one side of the package, and wherein the first thermal pad and the second thermal pad are internally connected to the source.

13. The embedded die package of claim 12, wherein vias comprising electrically conductive and thermally conductive material provide electrical connection and thermal contact between the first thermal pad and the source, and between the second thermal pad and the source.

14. An embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a first conductive layer comprising a leadframe supporting the die and providing electrical contact areas and a primary thermal pad, the thermal contact area of the die being in thermal contact with the primary thermal pad of the leadframe;
a first dielectric build-up layer embedding the die and the leadframe;
a second conductive layer on the first dielectric build-up layer;
the second conductive layer being patterned to define interconnect areas;
the interconnect areas of the second conductive layer being connected by electrically conductive vias to respective electrical contact areas of the power semiconductor device and electrical contact areas of the leadframe; and
a second dielectric build-up layer on the second conductive layer;
a third conductive layer on the second dielectric build-up layer;
the third conductive layer being patterned to define a secondary thermal pad;
wherein the primary and secondary thermal pads providing for dual-side cooling.

15. The embedded die package of claim 14, comprising fourth conductive layer underlying the first conductive layer and separated therefrom by another dielectric build-up layer, the fourth conductive layer forming an external thermal pad which is in thermal contact with the primary thermal pad of the first conductive layer, and the fourth conductive layer providing external electrical contact areas which are interconnected to respective contact areas of the first conductive layer.

16. The embedded die package of claim 15, wherein thermally conductive vias provide said thermal contact between the first thermal pad and the external thermal pad.

17. The embedded die package of claim 14, wherein the power semiconductor device comprises a lateral power transistor, wherein said electrical contact areas of the power semiconductor device comprise electrical contact areas for a source, drain and gate of the lateral power transistor on the bottom-side of the package, and wherein the first thermal pad and the second thermal pad are internally connected to the source.

18. The embedded die package of claim 17, wherein vias comprising electrically conductive and thermally conductive material provide electrical connection and thermal contact between the first thermal pad and the source, and between the second thermal pad and the source.

19. An embedded die package comprising a laminated body and a die comprising a power semiconductor device, the die being embedded within the laminated body, wherein:
the die comprises a patterned layer of conductive metallization on a front-side of the die providing electrical contact areas of the power semiconductor device, and a thermal contact area on a back-side of the die; and
a layer stack of the laminated body comprises:
a core comprising at least one dielectric layer which embeds the die;
a first dielectric build-up layer on a first side of the core;
a first conductive layer on the first dielectric build-up layer;
the first conductive layer being patterned to define a primary thermal pad and electrical interconnect areas, the thermal contact area of the die being in thermal contact with the primary thermal pad;
a second dielectric build-up layer on a second side of the core,
a second conductive layer on the second dielectric build-up layer,
the second conductive layer being patterned to define electrical contact areas, the interconnect areas of the first conductive layer being connected by electrically conductive vias to respective electrical contact areas of the power semiconductor device and respective electrical contact areas of the first conductive layer;
a third dielectric build-up layer on the first conductive layer;
a third conductive layer on the third dielectric build up layer;
the third conductive layer being patterned to define a secondary thermal pad;
wherein the primary and secondary thermal pads providing for dual-side cooling.

20. The embedded die package of claim 19, wherein thermal vias provide for said thermal contact between the first thermal pad and the thermal contact on the back-side of the die.

21. The embedded die package of claim 19, comprising a fourth conductive layer underlying the first conductive layer and separated therefrom by another dielectric build-up layer, the fourth conductive layer forming an external thermal pad which is in thermal contact with the first thermal pad of the first conductive layer.

22. The embedded die package of claim 21, wherein thermally conductive vias provide said thermal contact between the first thermal pad and the external thermal pad.

23. The embedded die package of claim 19, wherein the power semiconductor device comprises a lateral power transistor, wherein said electrical contact areas of the power semiconductor device comprise electrical contact areas for a source, drain and gate of the lateral power transistor on the bottom-side of the package, and wherein the first thermal pad and the second thermal pad are internally connected to the source.

24. The embedded die package of claim 23, wherein vias comprising electrically conductive and thermally conductive material provide electrical connection and thermal contact between the first thermal pad and the source, and between the second thermal pad and the source.

25. The embedded die package of claim 6, wherein said dielectric layers or dielectric build-up layers comprise any one of: a glass-fiber reinforced resin composition; a glass-fiber reinforced epoxy resin composition; a dielectric resin build-up layer; a dielectric epoxy build-up layer; a build-up layer which is formed from an ABF (Ajinimoto Build-up Film); and a combination thereof.

26. The embedded die package of claim 6, wherein said conductive layers and conductive vias comprise copper.

27. The embedded die package of claim 6, wherein the power semiconductor device comprises at least one high voltage, high current lateral GaN HEMT rated for operation at ≥100V or ≥600V.

28. The embedded die package of claim 27, wherein the at least one GaN HEMT is rated for operation at a temperature ≥75 C, or for operation at a temperature ≥100 C.

29. The embedded die package of claim 6, comprising at least one of the following features:
a) the power semiconductor device comprises: at least one lateral GaN transistor wherein said contact areas of the power semiconductor device comprise source, drain and gate contact areas of the lateral GaN power transistor;
b) the power semiconductor device comprises: at least one lateral GaN diode, wherein said contact areas of the power semiconductor device comprise anode and cathode contact areas of the lateral GaN diode;
c) the die comprises at least one of: driver circuitry, control circuitry and other components integrated with the power semiconductor device;
d) the power semiconductor device is co-packaged with other components embedded in the layer stack;
e) the power semiconductor device comprises a power semiconductor diode device and said electrical contacts of the power semiconductor device are anode and cathode;
f) the power semiconductor device comprises any one of: at least one power transistor; at least one power diode; a combination of at least one power transistor and at least one power diode;
g) the power semiconductor device comprises a plurality of power transistors configured as one of a half-bridge, a full-bridge and other switching topologies;
h) the power semiconductor device is fabricated from any one of: GaN and other III-Nitride semiconductor materials; and Si, SiC and other Group IV materials;
i) the die comprises at least one of: driver circuitry, control circuitry and other components integrated with the power semiconductor device;
j) the power semiconductor device is co-packaged with other components embedded in the layer stack;
k) wherein the power semiconductor device comprises at least one of a GaN HEMT, a GaN diode, a SiC MOSFET, a SiC diode, a Si IGBT, and a Si diode.
l) the power semiconductor device comprises: at least one lateral GaN transistor wherein said electrical contact areas of the power semiconductor device comprise source and drain contact areas of the lateral GaN power transistor; and
m) the power semiconductor device comprises: at least one lateral GaN diode, wherein electrical contact areas of the power semiconductor device comprise anode and cathode contact areas of the lateral GaN diode.
